(19) United States
(12) Patent Application Publication
(10) Pub. No.: US 2012/0188836 A1
(43) Pub. Date: Jul. 26, 2012

(54) SEMICONDUCTOR MEMORY APPARATUS

(75) Inventors: Kang Seol LEE, Icheon-si (KR); Tae Sik YUN, Icheon-si (KR)

(73) Assignee: HYNIX SEMICONDUCTOR INC., Icheon-si (KR)

(21) Appl. No.: 13/356,771

(22) Filed: Jan. 24, 2012

(30) Foreign Application Priority Data
Jan. 25, 2011 (KR) 10-2011-0007291

(51) Int. Cl. G11C 7/12; G11C 7/06

(52) U.S. Cl. 365/203; 365/207

(57) ABSTRACT

A semiconductor memory apparatus includes a bit line sense amplifier unit and a driving voltage supply unit. The bit line sense amplifier unit senses and amplifies a signal provided from a memory cell using a pull-up driving voltage provided through a pull-up power line and a pull-down driving voltage provided through a pull-down power line. The driving voltage supply unit supplies the pull-down driving voltage having a first pull-down driving force during a first amplification period, and supplies the pull-down driving voltage having a second pull-down driving force greater than the first pull-down driving force during a second amplification period after the first amplification period.

### CROSS-REFERENCES TO RELATED APPLICATION

The present application claims priority under 35 U.S.C. §119(a) to Korean application number 10-2011-0007291, filed on Jan. 25, 2011, in the Korean Intellectual Property Office, which is incorporated herein by reference in its entirety as set forth in full.

### BACKGROUND

1. Technical Field

The present invention relates to a semiconductor memory apparatus, and more particularly, to a technology for sensing and amplifying data of a memory cell using a bit line sense amplifier circuit.

2. Related Art

In general, a semiconductor memory apparatus receives external power so as to generate an internal voltage having various voltage levels, and operates an internal circuit using the internal voltage. As the semiconductor memory apparatus is more highly integrated, the voltage levels of the external power and the internal voltage are gradually lowered. Particularly, a bit line sense amplifier circuit for sensing and amplifying data stored in a memory cell uses an over driving voltage so as to reduce an amplification time thereof.

The bit line sense amplifier circuit senses a difference in voltage between a main bit line and a sub bit line, and amplifies the sensed difference in voltage. In this case, an offset voltage is generated due to a difference in characteristics between transistors constituting the bit line sense amplifier circuit, coupling between adjacent lines, and the like. That is, the bit line sense amplifier circuit should sense a difference in voltage between the main bit line and the sub bit line. However, if the offset voltage is greater than a difference in voltage between the main bit line and the sub bit line, the bit line sense amplifier circuit cannot correctly amplify data.

Particularly, when the bit line sense amplifier circuit uses an over driving voltage so as to reduce an amplification time thereof, the offset voltage of the bit line sense amplifier circuit is increased more due to power noise. Therefore, it is required to develop a technology for reducing an offset voltage of a bit line sense amplifier circuit.

### SUMMARY

A semiconductor memory apparatus capable of reducing power noise of a bit line sense amplifier circuit is described herein.

A semiconductor memory apparatus capable of sensing and amplifying data by decreasing an offset voltage of a bit line sense amplifier circuit is described herein.

In one embodiment of the present invention, a semiconductor memory apparatus includes a bit line sense amplifier unit configured to sense and amplify a signal provided from a memory cell using a pull-up driving voltage provided through a pull-up power line and a pull-down driving voltage provided through a pull-down power line; and a driving voltage supply unit configured to supply the pull-down driving voltage having a first pull-down driving force during a first amplification period, and supply the pull-down driving voltage having a second pull-down driving force greater than the first pull-down driving force during a second amplification period after the first amplification period. In the semiconductor memory apparatus, the driving voltage supply unit supplies the pull-up driving voltage having a first voltage level during a first period of the second amplification period, and supplies the pull-up driving voltage having a second voltage level lower than the first voltage level during a second period after the first period.

In another embodiment of the present invention, the semiconductor memory apparatus includes a bit line sense amplifier unit configured to sense and amplify a signal provided from a memory cell using a pull-up driving voltage provided through a pull-up power line and a pull-down driving voltage provided through a pull-down power line; and a driving voltage supply unit configured to supply the pull-up driving voltage having a first pull-up driving force during a first amplification period, and supply the pull-up driving voltage having a second pull-up driving force greater than the first pull-up driving force during a second amplification period after the first amplification period. In the semiconductor memory apparatus, the driving voltage supply unit supplies the pull-up driving voltage having a first voltage level during a first period of the second amplification period, and supplies the pull-up driving voltage having a second voltage level lower than the first voltage level during a second period after the first period.

In still another embodiment of the present invention, the semiconductor memory apparatus includes a bit line sense amplifier unit configured to sense and amplify a signal provided from a memory cell using a pull-up driving voltage provided through a pull-up power line and a pull-down driving voltage provided through a pull-down power line; and a driving voltage supply unit configured to supply the pull-down/pull-up driving voltage having a first pull-down/first pull-up driving force during a first amplification period, and supply the pull-down/pull-up driving voltage having a second pull-down/pull-up driving force greater than the first pull-down/first pull-up driving force during a second amplification period after the first amplification period. In the semiconductor memory apparatus, the driving voltage supply unit supplies the pull-up driving voltage having a first voltage level during a first period of the second amplification period, and supplies the pull-up driving voltage having a second voltage level lower than the first voltage level during a second period after the first period.

In still another embodiment of the present invention, the semiconductor memory apparatus includes a bit line sense amplifier unit configured to sense and amplify a signal provided from a memory cell using a pull-up driving voltage provided through a pull-up power line and a pull-down driving voltage provided through a pull-down power line; and a driving voltage supply unit configured to supply the pull-down/pull-up driving voltage having a first pull-down/first pull-up driving force during a first amplification period, in which the pull-down driving voltage is supplied faster by a predetermined time than the pull-up driving voltage, and supply the pull-down/pull-up driving voltage having a second pull-down/pull-up driving force greater than the first pull-down/first pull-up driving force during a second amplification period after the first amplification period. In the semiconductor memory apparatus, the driving voltage supply unit supplies the pull-up driving voltage having a first voltage level during a first period of the second amplification period, and supplies the pull-up driving voltage having a second voltage level lower than the first voltage level during a second period after the first period.

### BRIEF DESCRIPTION OF THE DRAWINGS

Features, aspects, and embodiments are described in conjunction with the attached drawings, in which:

FIG. 1 is a configuration diagram of a semiconductor memory apparatus according to one embodiment;

FIG. 2 is a timing diagram illustrating an internal operation of the semiconductor memory apparatus of FIG. 1;

FIG. 3 is a configuration diagram of a semiconductor memory apparatus according to another embodiment;

FIG. 4 is a timing diagram illustrating an internal operation of the semiconductor memory apparatus of FIG. 3;

FIG. 5 is a configuration diagram of a semiconductor memory apparatus according to still another embodiment;

FIG. 6A is a timing diagram illustrating a first internal operation of the semiconductor memory apparatus of FIG. 5; and

FIG. 6B is a timing diagram illustrating a second internal operation of the semiconductor memory apparatus of FIG. 5.

### DETAILED DESCRIPTION

Hereinafter, a semiconductor memory apparatus according to embodiments of the present invention will be described below with reference to the accompanying drawings through example embodiments.

For reference, a term, symbol or sign used when designating an element or block in the drawings and detailed description may be represented for each specific unit as occasion demands, and therefore, a like term, symbol or sign cannot designate a like element or block in the entire circuit. Further, data stored in the semiconductor memory apparatus is divided into a high level (H) or low level (L) corresponding to a voltage level thereof, and may be represented by ‘1’ or ‘0,’ respectively. Here, values of the data are divided depending on the level of voltage and the amplitude of current. In the case of binary data, the high level is defined as a high voltage, and the low level is defined as a voltage lower than the high level.

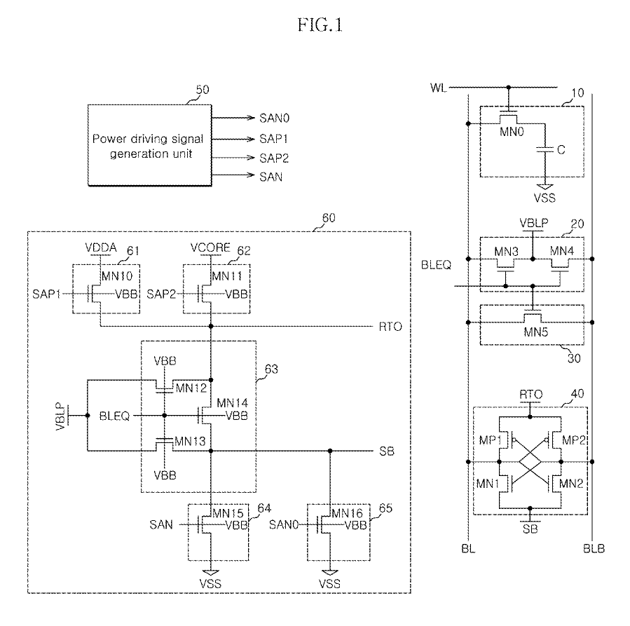

FIG. 1 is a configuration diagram of a semiconductor memory apparatus according to one embodiment.

The semiconductor memory apparatus according to this embodiment includes a brief configuration for illustrating the technical spirit of an embodiment of the present invention.

Referring to FIG. 1, the semiconductor memory apparatus includes a memory cell 10, a bit line precharge unit 20, a bit line equalizing unit 30, a bit line sense amplifier unit 40, a power driving signal generation unit 50 and a driving voltage supply unit 60.

A detailed configuration and main operation of the semiconductor memory apparatus configured as described above are as follows.

The memory cell 10 includes a cell transistor MN0 and a cell capacitor C. The cell transistor MN0 controls a data access to the cell capacitor C.

If an equalizing signal BLEQ is activated to a high level, the bit line precharge unit 20 precharges a main bit line BL and a sub bit line BLB to a precharge voltage VBLP. For reference, the precharge voltage VBLP is set to an intermediate level of a voltage VCORE when high-level data is stored in the cell capacitor C. In this embodiment, the bit line precharge unit 20 includes an NMOS transistor MN3 connected between the main bit line BL and a precharge voltage terminal VBLP and the NMOS transistor MN3 controlled by the equalizing signal BLEQ. The bit line precharge unit 20 may also include an NMOS transistor MN4 connected between the sub bit line BLB and the precharge voltage terminal VBLP and the NMOS transistor MN4 is controlled by the equalizing signal BLEQ. When the equalizing signal BLEQ is activated to the high level, the bit line equalizing unit 30 electrically connects the main bit line BL and the sub bit line BLB to each other, so that the bit line pair BL and BLB are formed to have the same level, i.e., the precharge voltage VBLP. In this embodiment, the bit line equalizing unit 30 includes an NMOS transistor MN5 connected to the main bit line BL and the sub bit line BLB and controlled by the equalizing signal BLEQ.

That is, before the memory cell 10 performs a charge-share operation with the main bit line BL, the bit line pair BL and BLB is precharged to the precharge voltage VBLP. If an active command is applied to a word line WL to be activated to the high level, the cell transistor MN0 of the memory cell 10 is turned on so that a charge share between the cell capacitor C and the bit line BL occurs. In this case, the voltage of the main bit line BL is determined according to the quantity of electric charges.

The main bit line BL and the sub bit line BLB were precharged to the same voltage level before the charge share, and a predetermined voltage difference (ΔV) between the main bit line BL and the sub bit line BLB after the charge share. The bit line sense amplifier unit 40 decides and amplifies data stored in the cell capacitor C of the memory cell 10 by sensing the voltage difference (ΔV) between the bit line pair BL and BLB.

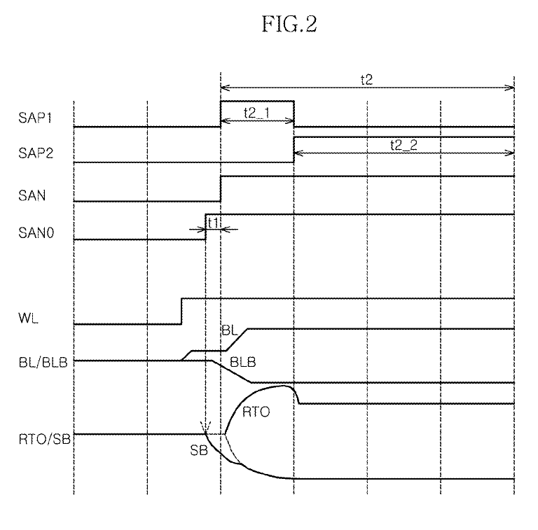

FIG. 2 is a timing diagram illustrating an internal operation of the semiconductor memory apparatus of FIG. 1.

An operation of the semiconductor memory apparatus will be described with reference to FIG. 1 and the timing diagram of FIG. 2. For reference, it is assumed that high-level data is stored in the cell capacity C.

The bit line sense amplifier unit 40 senses and amplifies a signal provided from the memory cell 10 using a pull-up driving voltage provided through a pull-up power line RTO and a pull-down driving voltage provided through a pull-down power line SB. In this embodiment, the bit line sense amplifier unit 40 senses the voltage difference (ΔV) between the main bit line BL and the sub bit line BLB, and includes a differential amplifier circuit MP1, MP2, MN1 and MN2 for amplifying the voltage difference (ΔV). That is, the differential amplifier circuit MP1, MP2, MN1 and MN2 is configured as a cross couple latch amplifier including two PMOS transistors MP1 and MP2 and two NMOS transistor MN1 and MN2.

The power driving signal generation unit 50 generates a first pull-down driving signal SAN0 activated at a time of a first amplification period t1, a second pull-down driving signal SAN activated at a time of a second amplification period t2, a first pull-up driving signal SAP1 activated during a first period t2_1 of the second amplification period t2, and a second pull-up driving signal SAP2 activated during a second period t2_2 of the second amplification period t2.

The driving voltage supply unit 60 supplies a pull-down driving voltage having a first pull-down driving force during the first amplification period t1, and supplies a pull-down driving voltage having a second pull-down driving force greater than the first full-down driving force during the second amplification period t2 after the first amplification period t1.

The driving voltage supply unit 60 supplies a pull-up driving voltage having a first voltage level VDDA during the first period t2_1 of the second amplification period t2, and supplies a pull-up driving voltage having a second voltage level VCORE lower than the first voltage level VDDA during the second period t2_2 after the first period t2_1 of the second amplification period t2. Here, the pull-up driving voltage having the first voltage level VDDA is a voltage for an over driving operation.

In this embodiment, the driving voltage supply unit 60 includes a first pull-down driving unit 65, a second pull-down driving unit 64, a first pull-up driving unit 61, a second pull-up driving unit 62 and a precharge unit 63. For reference, NMOS transistors constituting the driving voltage supply unit 60 receive a negative voltage VBB as a substrate bias voltage. That is, when the NMOS transistor drives a driving voltage, the negative voltage VBB is used as the substrate bias voltage so as to minimize a voltage drop. When a PMOS transistor is used as the NMOS transistor, the voltage drop is minimized using a positive voltage VPP as the substrate bias voltage.

The first pull-down driving unit 65 drives the pull-down driving voltage having the first pull-down driving force to the pull-down power line SB in response to the first pull-down driving signal SAN0. In this embodiment, the first pull-down driving unit 65 includes an NMOS transistor MN16 connected between the pull-down power line SB and a ground voltage terminal VSS and controlled by the first pull-down driving signal SAN0. Here, the NMOS transistor MN16 is designed to have the first pull-down driving force. For reference, according to embodiments, the first pull-down driving unit 65 can be configured as a PMOS transistor having the first pull-down driving force.

The second pull-down driving unit 64 drives the pull-down driving voltage having the second pull-down driving force to the pull-down power line SB in response to the second pull-down driving signal SAN activated after the first pull-down driving signal SAN0 is activated. In this embodiment, the second pull-down driving unit 64 includes an NMOS transistor MN15 connected between the pull-down power line SB and the ground voltage terminal VSS and controlled by the second pull-down driving signal SAN. Here, the NMOS transistor MN15 is designed to have the second pull-down driving force greater than the first pull-down driving force. Because pull-down driving force is great, a speed at which the voltage of the pull-down power line SB is dropped to the ground voltage is increased.

The first pull-up driving unit 61 drives the pull-up driving voltage having the first voltage level VDDA to the pull-up power line RTO in response to the first pull-up driving signal SAP1. That is, the first pull-up driving unit 61 drives an over driving voltage VDDA to the pull-up power line RTO. In this embodiment, the first pull-up driving unit 61 includes an NMOS transistor MN10 connected between a first power voltage terminal VDDA and the pull-up power line RTO and controlled by the first pull-up driving signal SAP1.

The second pull-up driving unit 62 drives the pull-up driving voltage having the second voltage level VCORE to the pull-up power line RTO in response to the second pull-up driving signal SAP2 activated after the first pull-up driving signal SAP1 is activated. In this embodiment, the second pull-up driving unit 62 includes an NMOS transistor MN11 connected between a second power voltage terminal VCORE and the pull-up power line RTO and the NMOS transistor MN11 may be controlled by the second pull-up driving signal SAP2. For reference, the second voltage level is a voltage formed in the cell capacitor C when high-level data is stored.

The precharge unit 63 precharges the pull-up power line RTO and the pull-down power line SB to the precharge voltage VBLP in response to a precharge signal BLEQ. In this embodiment, the precharge unit 63 includes an equalizing NMOS transistor MN14 connected between the pull-up power line RTO and the pull-down power line SB and controlled by the precharge signal BLEQ, a first precharge NMOS transistor MN12 connected between the precharge voltage terminal VBLP and the pull-up voltage line RTO and may be controlled by the precharge signal BLEQ, and a second precharge NMOS transistor MN13 connected between the precharge voltage terminal VBLP and the pull-down power line SB and may be controlled by the precharge signal BLEQ. For reference, in this embodiment, the precharge unit 63 is configured so that the equalizing NMOS transistor MN14 and the first and second precharge NMOS transistors MN12 and MN13 are simultaneously controlled through the precharge signal BLEQ. However, according to embodiments, the precharge unit 63 can be configured so that the equalizing NMOS transistor MN14 and the first and second precharge NMOS transistors are controlled through an equalizing signal and precharge signals, respectively. That is, in this embodiment, the equalizing NMOS transistor MN14 and the first and second precharge NMOS transistors are not designed to use the precharge signal BLEQ divided into the equalizing signal and the precharge signal, but are designed to commonly use the precharge signal BLEQ.

As described above, the semiconductor memory apparatus according to this embodiment supplies the pull-up driving voltage and the pull-down driving voltage to the bit line sense amplifier unit 40 so that the bit line sense amplifier unit 40 can perform an amplification operation through three step amplification periods.

First, the driving voltage supply unit 60 supplies a pull-down driving voltage having a relatively small first pull-down driving force during a first amplification period t1.

Subsequently, the driving voltage supply unit 60 supplies a pull-down driving voltage having a second pull-down driving force greater than the first pull-down driving force during a second amplification period t2 after the first amplification period t1. In this case, the second amplification period t2 is divided into two periods. That is, the driving voltage supply unit 60 supplies a pull-up driving voltage having a first voltage level VDDA during a first period t2_1 of the second amplification period t2, and supplies a pull-up driving voltage having a second voltage level VCORE lower than the first voltage level VDDA during a second period t2_2 after the first period t2_1 of the second amplification period t2. Here, the pull-up driving voltage having the first voltage level VDDA is a voltage for an over driving operation, and therefore, the bit line sense amplifier unit 40 performs an amplification operation using an over driving voltage VDDA during the first period t2_1 of the second amplification period t2.

When the pull-down driving voltage having a relatively small driving force is first supplied during the first amplification period t1 before the over driving operation is performed, the voltage of the pull-down power line SB is gently dropped. Although the pull-up driving voltage having the over driving voltage level VDDA is supplied at the time when the over driving voltage is supplied, i.e., at the time of the first period t2_1 of the second amplification period t2, the voltage of the pull-down power line SB is gently dropped. Thus, power noise is reduced, and accordingly, the offset voltage of the bit line sense amplifier unit 40 is decreased.

As the voltages of the pull-up power line RTO and the pull-down power line SB rapidly fluctuate, the power noise supplied to the bit line sense amplifier unit 40 is increased, and therefore, the offset voltage of the bit line sense amplifier unit 40 is increased. Thus, in this embodiment, the offset voltage of the bit line sense amplifier unit 40, caused by the power noise, is decreased by driving the pull-down driving voltage having a relatively small driving force to the pull-down power line SB before the over driving operation is performed. Accordingly, the bit line sense amplifier unit 40 can more stably amplify data, and the reliability of data amplification can be improved.

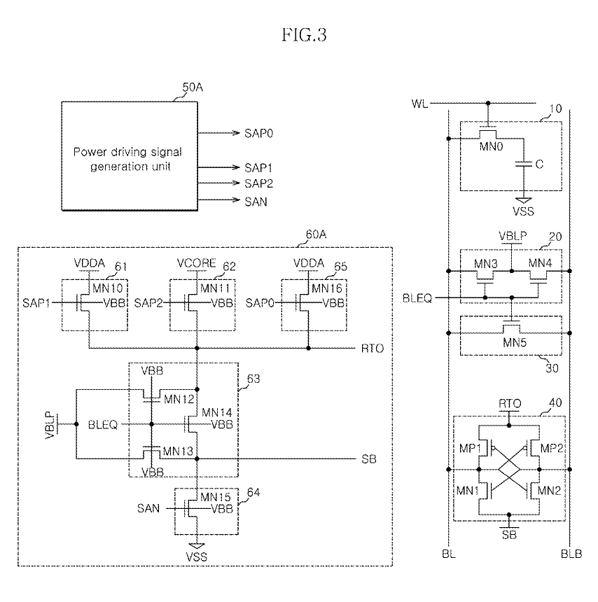

FIG. 3 is a configuration diagram of a semiconductor memory apparatus according to another embodiment.

The semiconductor memory apparatus according to this embodiment includes a brief configuration for clearly illustrating a technical spirit of the present invention.

Referring to FIG. 3, the semiconductor memory apparatus includes a memory cell 10, a bit line precharge unit 20, a bit line equalizing unit 30, a bit line sense amplifier unit 40, a power driving signal generation unit 50A and a driving voltage supply unit 60A.

A detailed configuration and main operation of the semiconductor memory apparatus configured as described above are as follows.

The memory cell 10 includes a cell transistor MN0 and a cell capacitor C. The cell transistor MN0 controls a data access to the cell capacitor C.

If an equalizing signal BLEQ is activated to a high level, the bit line precharge unit 20 precharges a main bit line BL and a sub bit line BLB to a precharge voltage VBLP. For reference, the precharge voltage VBLP is set to an intermediate level of a voltage VCORE when high-level data is stored in the cell capacitor C. In this embodiment, the bit line precharge unit 20 includes an NMOS transistor MN3 connected between the main bit line BL and a precharge voltage terminal VBLP and is controlled by the equalizing signal BLEQ, and an NMOS transistor MN4 connected between the sub bit line BLB and the precharge voltage terminal VBLP and is controlled by the equalizing signal BLEQ. Meanwhile, when the equalizing signal BLEQ is activated to the high level, the bit line equalizing unit 30 electrically connects the main bit line BL and the sub bit line BLB to each other, so that the bit line pair BL and BLB are formed to have the same level, i.e., the precharge voltage VBLP. In this embodiment, the bit line equalizing unit 30 includes an NMOS transistor MN5 connected to the main bit line BL and the sub bit line BLB and is controlled by the equalizing signal BLEQ.

That is, before the memory cell 10 performs a charge-share operation with the main bit line BL, the bit line pair BL and BLB is precharged to the precharge voltage VBLP. Then, if an active command is applied to a word line WL to be activated to the high level, the cell transistor MN0 of the memory cell 10 is turned on so that a charge share between the cell capacitor C and the bit line BL occurs. In this case, the voltage of the main bit line BL is determined according to the quantity of electric charges.

The main bit line BL and the sub bit line BLB were precharged to the same voltage level before the charge share, and a predetermined voltage difference (ΔV) between the main bit line BL and the sub bit line BLB after the charge share. The bit line sense amplifier unit 40 decides and amplifies data stored in the cell capacitor C of the memory cell 10 by sensing a voltage difference (ΔV) between the bit line pair BL and BLB.

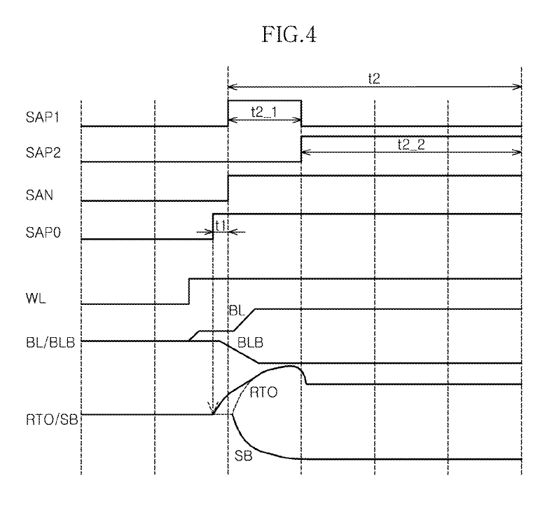

FIG. 4 is a timing diagram illustrating an internal operation of the semiconductor memory apparatus of FIG. 3.

A main operation of the semiconductor memory apparatus is described with reference to FIG. 3 and the timing diagram of FIG. 4. For reference, it is assumed that high-level data is stored in the cell capacity C.

The bit line sense amplifier unit 40 senses and amplifies a signal provided from the memory cell 10 using a pull-up driving voltage provided through a pull-up power line RTO and a pull-down driving voltage provided through a pull-down power line SB. In this embodiment, the bit line sense amplifier unit 40 senses the voltage difference (ΔV) between the main bit line BL and the sub bit line BLB, and includes a differential amplifier circuit MP1, MP2, MN1 and MN2 for amplifying the voltage difference (ΔV). That is, the differential amplifier circuit MP1, MP2, MN1 and MN2 is configured as a cross couple latch amplifier including two PMOS transistors MP1 and MP2 and two NMOS transistor MN1 and MN2.

The power driving signal generation unit 50A generates a first pull-up driving signal SAP0 activated at the time of a first amplification period t1, a second pull-down driving signal SAP1 activated during a first period t2_1 of a second amplification period t2, a third pull-up driving signal SAP2 activated during a second period t2_2 of the second amplification period t2, and a pull-down driving signal SAN activated at the time of the second amplification period t2.

Meanwhile, the driving voltage supply unit 60A supplies a pull-up driving voltage having a first pull-up driving force during the first amplification period t1, and supplies a pull-up driving voltage having a second pull-up driving force greater than the first pull-up driving force during the second amplification period t2 after the first amplification period t1. Because the pull-up driving force is great, the rising speed of the voltage of the pull-up power line RTO is increased.

The driving voltage supply unit 60A supplies a pull-up driving voltage having a first voltage level VDDA during the first period t2_1 of the second amplification period t2, supplies a pull-up driving voltage having a second voltage level VCORE lower than the first voltage level VDDA during the second period t2_2 after the first period t2_1 of the second amplification period t2, and supplies pull-down driving voltage during the second amplification period t2. Here, the pull-up driving voltage having the first voltage level VDDA is a voltage for an over driving operation.

In this embodiment, the driving voltage supply unit 60A includes a first pull-up driving unit 65, a second pull-up driving unit 61, a third pull-up driving unit 62, a pull-down driving unit 64 and a precharge unit 63. For reference, NMOS transistors constituting the driving voltage supply unit 60A receive a negative voltage VBB as a substrate bias voltage. That is, when the NMOS transistor drives a driving voltage, the negative voltage VBB is used as the substrate bias voltage so as to minimize a voltage drop. When a PMOS transistor is used as the NMOS transistor, the voltage drop is minimized using a positive voltage VPP as the substrate bias voltage.

The first pull-up driving unit 65 drives the pull-up driving voltage having the first pull-up driving force to the pull-up power line RTO in response to the first pull-up driving signal SAP0. In this embodiment, the first pull-up driving unit 65 includes an NMOS transistor MN16 connected between a first power voltage terminal VDDA and the pull-up power line RTO and controlled by the first pull-up driving signal SAP0. Here, the NMOS transistor MN16 is designed to have the first pull-up driving force. For reference, according to embodiments, the first pull-up driving unit 65 can be configured as a PMOS transistor having the first pull-up driving force.

The second pull-up driving unit 61 drives the pull-up driving voltage having the first voltage level VDDA to the pull-up power line RTO in response to the second pull-up driving signal SAP1 activated after the first pull-up driving signal SAP0 is activated. That is, the second pull-up driving unit 61 drives the pull-up driving voltage having the first voltage level VDDA to the pull-up power line RTO. In this embodiment, the second pull-up driving unit 61 includes an NMOS transistor MN10 connected between the first power voltage terminal VDDA and the pull-up power line RTO and controlled by the second pull-up driving signal SAP1. Here, the NMOS transistor MN10 is designed to have the second pull-up driving force which may be greater than the first pull-up driving force. Because the pull-up driving force is great, the rising speed of the voltage of the pull-up power line RTO is increased.

The third pull-up driving unit 62 drives the pull-up driving voltage having the second voltage level VCORE to the pull-up power line RTO in response to the third pull-up driving signal SAP2 activated after the second pull-up driving signal SAP1 is activated. For reference, the second voltage level VCORE is a voltage formed in the cell capacitor C when high-level data is stored. In this embodiment, the third pull-up driving unit 62 includes an NMOS transistor MN11 connected between a second power voltage terminal VCORE and the pull-up power line RTO and controlled by the third pull-up driving signal SAP2.

The pull-down driving unit 64 drives the pull-down driving voltage to the pull-down power line SB in response to the pull-down driving signal SAN. In this embodiment, the pull-down driving unit 64 includes an NMOS transistor MN15 connected between a ground voltage terminal VSS and the pull-down power line SB and controlled by the pull-down driving signal SAN.

The precharge unit 63 precharges the pull-up power line RTO and the pull-down power line SB to the precharge voltage VBLP in response to a precharge signal BLEQ. In this embodiment, the precharge unit 63 includes an equalizing NMOS transistor MN14 connected between the pull-up power line RTO and the pull-down power line SB and controlled by the precharge signal BLEQ, a first precharge NMOS transistor MN12 connected between the precharge voltage terminal VBLP and the pull-up voltage line RTO and controlled by the precharge signal BLEQ, and a second precharge NMOS transistor MN13 connected between the precharge voltage terminal VBLP and the pull-down power line SB and controlled by the precharge signal BLEQ. For reference, in this embodiment, the precharge unit 63 is configured so that the equalizing NMOS transistor MN14 and the first and second precharge NMOS transistors MN12 and MN13 are simultaneously controlled through the precharge signal BLEQ. However, according to embodiments, the precharge unit 63 can be configured so that the equalizing NMOS transistor MN14 and the first and second precharge NMOS transistors are controlled through an equalizing signal and precharge signals, respectively. That is, in this embodiment, the equalizing NMOS transistor MN14 and the first and second precharge NMOS transistors are not designed to use the precharge signal BLEQ divided into the equalizing signal and the precharge signal, but are designed to commonly use the precharge signal BLEQ.

As described above, the semiconductor memory apparatus according to this embodiment supplies the pull-up driving voltage and the pull-down driving voltage to the bit line sense amplifier unit 40 so that the bit line sense amplifier unit 40 can perform an amplification operation through three step amplification periods.

First, the driving voltage supply unit 60A supplies a pull-up driving voltage having a relatively small first pull-up driving force during a first amplification period t1.

Subsequently, the driving voltage supply unit 60A supplies a pull-up driving voltage having a second pull-up driving force greater than the first pull-up driving force during a second amplification period t2 after the first amplification period t1. In this case, the second amplification period t2 is divided into two periods. That is, the driving voltage supply unit 60A supplies a pull-up driving voltage having a first voltage level VDDA during a first period t2_1 of the second amplification period t2, and supplies a pull-up driving voltage having a second voltage level VCORE lower than the first voltage level VDDA during a second period t2_2 after the first period t2_1 of the second amplification period t2. The driving voltage supply unit 60A supplies a pull-down driving voltage during the second amplification period t2. Here, the pull-up driving voltage having the first voltage level VDDA is a voltage for over driving operation, and therefore, the bit line sense amplifier unit 40 performs an amplification operation using an over driving voltage VDDA during the first period t2_1 of the second amplification period t2.

When the pull-up driving voltage having a relatively small driving force is first supplied during the first amplification period t1 before the over driving operation is performed, the voltage of the pull-up power line RTO is gently increased. Although the pull-up driving voltage having the over driving voltage level VDDA and the pull-down driving voltage are supplied at the time when the over driving voltage is supplied, i.e., at the time of the first period t2_1 of the second amplification period t2, the voltage of the pull-up power line RTO is gently increased. Thus, power noise is reduced, and accordingly, the offset voltage of the bit line sense amplifier unit 40 is decreased.

As the voltages of the pull-up power line RTO and the pull-down power line SB rapidly fluctuate, the power noise supplied to the bit line sense amplifier unit 40 is increased, and therefore, the offset voltage of the bit line sense amplifier unit 40 is increased. Thus, in this embodiment, the offset voltage of the bit line sense amplifier unit 40, caused by the power noise, is decreased by driving the pull-up driving voltage having a relatively small driving force to the pull-up power line RTO before the over driving operation is performed. Accordingly, the bit line sense amplifier unit 40 can more stably amplifies data, and the reliability of data amplification can be improved.

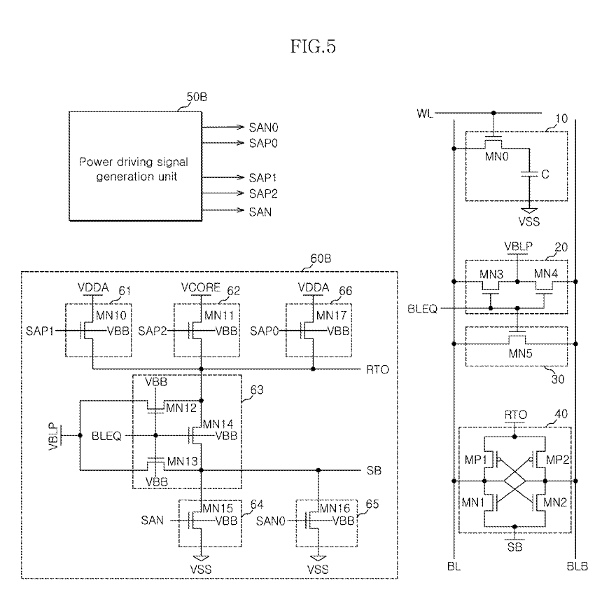

FIG. 5 is a configuration diagram of a semiconductor memory apparatus according to still another embodiment.

The semiconductor memory apparatus according to this embodiment includes a brief configuration for clearly illustrating the technical spirit of the present invention.

Referring to FIG. 5, the semiconductor memory apparatus includes a memory cell 10, a bit line precharge unit 20, a bit line equalizing unit 30, a bit line sense amplifier unit 40, a power driving signal generation unit 50B and a driving voltage supply unit 60B.

The detailed configuration and main operation of the semiconductor memory apparatus configured as described above are as follows.

The memory cell 10 includes a cell transistor MN0 and a cell capacitor C. The cell transistor MN0 controls a data access to the cell capacitor C.

If an equalizing signal BLEQ is activated to a high level, the bit line precharge unit 20 precharges a main bit line BL and a sub bit line BLB to a precharge voltage VBLP. For reference, the precharge voltage VBLP is set to an intermediate level of a voltage VCORE when high-level data is stored in the cell capacitor C. In this embodiment, the bit line precharge unit 20 includes an NMOS transistor MN3 connected between the main bit line BL and a precharge voltage terminal VBLP and controlled by the equalizing signal BLEQ, and an NMOS transistor MN4 connected between the sub bit line BLB and the precharge voltage terminal VBLP and controlled by the equalizing signal BLEQ. Meanwhile, when the equalizing signal BLEQ is activated to the high level, the bit line equalizing unit 30 electrically connects the main bit line BL and the sub bit line BLB to each other, so that the bit line pair BL and BLB are formed to have the same level, i.e., the precharge voltage VBLP. In this embodiment, the bit line equalizing unit 30 includes an NMOS transistor MN5 connected to the main bit line BL and the sub bit line BLB and controlled by the equalizing signal BLEQ.

That is, before the memory cell 10 performs a charge-share operation with the main bit line BL, the bit line pair BL and BLB is precharged to the precharge voltage VBLP. Then, if an active command is applied to a word line WL to be activated to the high level, the cell transistor MN0 of the memory cell 10 is turned on so that a charge share between the cell capacitor C and the bit line BL occurs. In this case, the voltage of the main bit line BL is determined according to the quantity of electric charges.

Meanwhile, the main bit line BL and the sub bit line BLB were precharged to the same voltage level before the charge share, and a predetermined voltage difference (ΔV) between the main bit line BL and the sub bit line BLB after the charge share. The bit line sense amplifier unit 40 decides and amplifies data stored in the cell capacitor C of the memory cell 10 by sensing the voltage difference (ΔV) between the bit line pair BL and BLB.

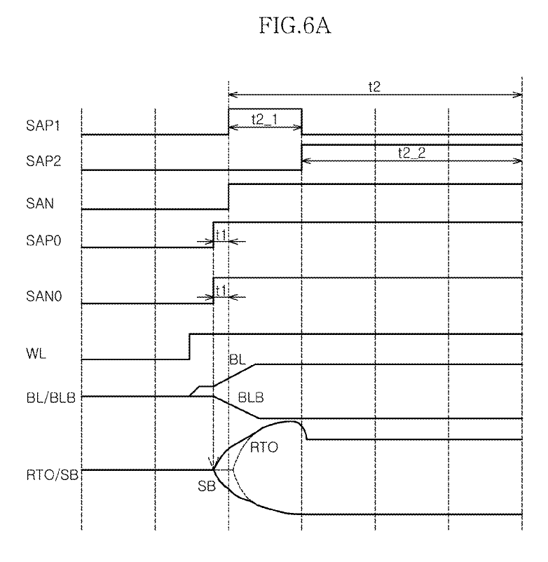

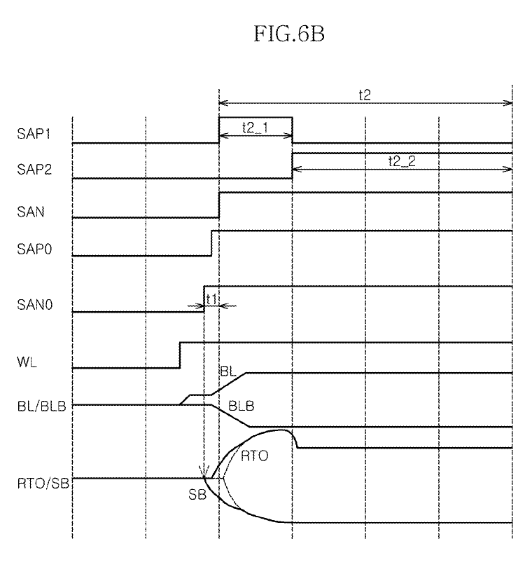

FIG. 6A is a timing diagram illustrating a first internal operation of the semiconductor memory apparatus of FIG. 5.

A main operation of the semiconductor memory apparatus will be described with reference to FIG. 5 and the timing diagram of FIG. 6A. For reference, it is assumed that high-level data is stored in the cell capacity C.

The bit line sense amplifier unit 40 senses and amplifies a signal provided from the memory cell 10 using a pull-up driving voltage provided through a pull-up power line RTO and a pull-down driving voltage provided through a pull-down power line SB. In this embodiment, the bit line sense amplifier unit 40 senses the voltage difference (ΔV) between the main bit line BL and the sub bit line BLB, and includes a differential amplifier circuit MP1, MP2, MN1 and MN2 for amplifying the voltage difference (ΔV). That is, the differential amplifier circuit MP1, MP2, MN1 and MN2 is configured as a cross couple latch amplifier including two PMOS transistors MP1 and MP2 and two NMOS transistor MN1 and MN2.

The power driving signal generation unit 50B generates a first pull-up driving signal SAP0 activated at the time of a first amplification period t1, a second pull-up driving signal SAP1 activated during a first period t2_1 of a second amplification period t2, a third pull-up driving signal SAP2 activated during a second period t2_2 of the second amplification period t2, a first pull-down driving signal SAN0 activated at the time of the first amplification period t1, and a second pull-down driving signal SAN activated at the time of the second amplification period t2.

The driving voltage supply unit 60B supplies a pull-down/pull-up driving voltage having a first pull-down/first pull-up driving force during the first amplification period t1, and supplies a pull-down/pull-up driving voltage having a second pull-down/second pull-up driving force greater than the first pull-down/first pull-up driving force during the second amplification period t2 after the first amplification period t1.

The driving voltage supply unit 60B supplies a pull-up driving voltage having a first voltage level VDDA during the first period t2_1 of the second amplification period t2, and supplies a pull-up driving voltage having a second voltage level VCORE lower than the first voltage level VDDA during the second period t2_2 after the first period t2_1 of the second amplification period t2. Here, the pull-up driving voltage having the first voltage level VDDA is a voltage for an over driving operation.

In this embodiment, the driving voltage supply unit 60B includes a first pull-down driving unit 65, a second pull-down driving unit 64, a first pull-up driving unit 66, a second pull-up driving unit 61, a third pull-up driving unit 62 and a precharge unit 63. For reference, NMOS transistors constituting the driving voltage supply unit 60B receive a negative voltage VBB as a substrate bias voltage. That is, when the NMOS transistor drives a driving voltage, the negative voltage VBB is used as the substrate bias voltage so as to minimize a voltage drop. In a case where a PMOS transistor is used as the NMOS transistor, the voltage drop is minimized using a positive voltage VPP as the substrate bias voltage.

The first pull-up driving unit 66 drives the pull-up driving voltage having the first pull-up driving force to the pull-up power line RTO in response to the first pull-up driving signal SAP0. In this embodiment, the first pull-up driving unit 66 includes an NMOS transistor MN17 connected between a first power voltage terminal VDDA and the pull-up power line RTO and controlled by the first pull-up driving signal SAP0. Here, the NMOS transistor MN17 is designed to have the first pull-up driving force. For reference, according to embodiments, the first pull-up driving unit 66 can be configured as a PMOS transistor having the first pull-up driving force.

The second pull-up driving unit 61 drives the pull-up driving voltage having the first voltage level VDDA to the pull-up power line RTO in response to the second pull-up driving signal SAP1 activated after the first pull-up driving signal SAP0 is activated. That is, the second pull-up driving unit 61 drives the pull-up driving voltage having the first voltage level VDDA to the pull-up power line RTO. In this embodiment, the second pull-up driving unit 61 includes an NMOS transistor MN10 connected between the first power voltage terminal VDDA and the pull-up power line RTO and controlled by the second pull-up driving signal SAP1. Here, the NMOS transistor MN10 is designed to have the second pull-up driving force greater than the first pull-up driving force. Because the pull-up driving force is great, the rising speed of the voltage of the pull-up power line RTO is increased.

The third pull-up driving unit 62 drives the pull-up driving voltage having the second voltage level VCORE to the pull-up power line RTO in response to the third pull-up driving signal SAP2 activated after the second pull-up driving signal SAP1 is activated. In this embodiment, the third pull-up driving unit 62 includes an NMOS transistor MN11 connected between a second power voltage terminal VCORE and the pull-up power line RTO and controlled by the third pull-up driving signal SAP2. For reference, the second voltage level VCORE is a voltage formed in the cell capacitor C when high-level data is stored.

The first pull-down driving unit 65 drives the pull-down driving voltage having the first pull-down driving force to the pull-down power line SB in response to the first pull-down driving signal SAN0. In this embodiment, the first pull-down driving unit 65 includes an NMOS transistor MN16 connected between the pull-down power line SB and the ground voltage terminal VSS and controlled by the pull-down driving signal SAN0. Here, the NMOS transistor MN16 is designed to have the first pull-down driving force. For reference, according to embodiments, the first pull-down driving unit 65 can be configured as a PMOS transistor having the first pull-down driving force.

The second pull-down driving unit 64 drives the pull-down driving voltage having the second pull-down driving force to the pull-down power line SB in response to the second pull-down driving signal SAN activated after the first pull-down driving signal SAN0 is activated. In this embodiment, the second pull-down driving unit 64 includes an NMOS transistor MN15 connected between the pull-down power line SB and the ground voltage terminal VSS and controlled by the second pull-down driving signal SAN. Here, the NMOS transistor MN15 is designed to have the second pull-down driving force greater than the first pull-down driving force. Because the pull-down driving force is great, the speed at which the voltage of the pull-down power line SB is dropped to the ground voltage VSS is increased.

The precharge unit 63 precharges the pull-up power line RTO and the pull-down power line SB to the precharge voltage VBLP in response to a precharge signal BLEQ. In this embodiment, the precharge unit 63 includes an equalizing NMOS transistor MN14 connected between the pull-up power line RTO and the pull-down power line SB and controlled by the precharge signal BLEQ, a first precharge NMOS transistor MN12 connected between the precharge voltage terminal VBLP and the pull-up voltage line RTO and controlled by the precharge signal BLEQ, and a second precharge NMOS transistor MN13 connected between the precharge voltage terminal VBLP and the pull-down power line SB and controlled by the precharge signal BLEQ. For reference, in this embodiment, the precharge unit 63 is configured so that the equalizing NMOS transistor MN14 and the first and second precharge NMOS transistors MN12 and MN13 are simultaneously controlled through the precharge signal BLEQ. However, according to embodiments, the precharge unit 63 can be configured so that the equalizing NMOS transistor MN14 and the first and second precharge NMOS transistors are controlled through an equalizing signal and precharge signals, respectively. That is, in this embodiment, the equalizing NMOS transistor MN14 and the first and second precharge NMOS transistors are not designed to use the precharge signal BLEQ divided into the equalizing signal and the precharge signal, but are designed to commonly use the precharge signal BLEQ.

As described above, the semiconductor memory apparatus according to this embodiment supplies the pull-up driving voltage and the pull-down driving voltage to the bit line sense amplifier unit 40 so that the bit line sense amplifier unit 40 can perform an amplification operation through three step amplification periods.

First, the driving voltage supply unit 60B supplies a pull-down/pull-up driving voltage having a relatively small first pull-down/first pull-up driving force during a first amplification period t1.

Subsequently, the driving voltage supply unit 60B supplies a pull-down/pull-up driving voltage having a second pull-down/second pull-up driving force greater than the first pull-down/first pull-up driving force during a second amplification period t2 after the first amplification period t1. In this case, the second amplification period t2 is divided into two periods. That is, the driving voltage supply unit 60B supplies a pull-up driving voltage having a first voltage level VDDA during a first period t2_1 of the second amplification period t2, and supplies a pull-up driving voltage having a second voltage level VCORE lower than the first voltage level VDDA during a second period t2_2 after the first period t2_1 of the second amplification period t2. Here, the pull-up driving voltage having the first voltage level VDDA is a voltage for over driving operation, and therefore, the bit line sense amplifier unit 40 performs an amplification operation using an over driving voltage VDDA during the first period t2_1 of the second amplification period t2.

When the pull-up/pull-down driving voltage having a relatively small driving force is first supplied during the first amplification period t1 before the over driving operation is performed, the voltage of the pull-up/pull-down power line RTO/SB is gently increased/decreased. Although the pull-up driving voltage having the over driving voltage level VDDA is supplied at the time when the over driving voltage is supplied, i.e., at the time of the first period t2_1 of the second amplification period t2, the voltage of the pull-up power line RTO is gently increased. Thus, power noise is reduced, and accordingly, the offset voltage of the bit line sense amplifier unit 40 is decreased.

As the voltages of the pull-up power line RTO and the pull-down power line SB rapidly fluctuate, the power noise supplied to the bit line sense amplifier unit 40 is increased, and therefore, the offset voltage of the bit line sense amplifier unit 40 is increased. Thus, in this embodiment, the offset voltage of the bit line sense amplifier unit 40, caused by the power noise, is decreased by driving the pull-up/pull-down driving voltage having a relatively small driving force to the pull-up/pull-down power line RTO/SB before the over driving operation is performed. Accordingly, the bit line sense amplifier unit 40 can more stably amplifies data, and the reliability of data amplification can be improved.

FIG. 6B is a timing diagram illustrating a second internal operation of the semiconductor memory apparatus of FIG. 5.

When the second internal operation is performed, the semiconductor memory apparatus of FIG. 5 activates the first pull-up driving signal SAP0 after the first pull-down driving signal SAN0 is activated.

In order to perform the second internal operation, the power driving signal generation unit 50B controls activation times of the first pull-up driving signal SAP0 and the first pull-down driving signal SAN0. That is, the power driving signal generation unit 50B generates the first pull-up driving signal SAP0 activated after the first pull-down driving signal SAN0 is activated during the first amplification period t1, the second pull-up driving signal SAP1 activated during the first period t2_1 of the second amplification period t2, the third pull-up driving signal SAP2 activated during the second period t2_2 of the second amplification period t2, the first pull-down driving signal SAN0 activated at the time of the first amplification period t1, and the second pull-down driving signal SAN activated at the time of the second amplification period t2. This is defined as still another embodiment. That is, a basic operation of this embodiment is substantially similar to that of the embodiment described with reference to FIG. 5. However, this embodiment is different from the embodiment described reference to FIG. 5 in that the activation times of the first pull-up driving signal SAP0 and the first pull-down driving signal SAN0 are additionally controlled.

The driving voltage driving unit 60B supplies the pull-down/pull-up driving voltage having the first pull-down/first pull-up driving force during the first amplification period t1. In this case, the pull-down driving voltage is supplied faster by a predetermined time than the pull-up driving voltage.

The driving voltage supply unit 60B supplies the pull-down/pull-up driving voltage having the second pull-down/second pull-up driving force greater than the first pull-down/first pull-up driving force during the second amplification period t2 after the first amplification period t1.

The driving voltage supply unit 60B supplies the pull-up driving voltage having the first voltage level VDDA during the first period t2_1 of the second amplification period t2, and supplies the pull-up driving voltage having the second voltage level VCORE lower than the first voltage level VDDA during the second period t2_2 of the second amplification period t2. Here, the pull-up driving voltage of the first voltage level VDDA is a voltage for over driving operation.

Particularly, the first pull-down driving unit 65 constituting the driving voltage supply unit 60B drives the pull-down driving voltage having the first pull-down driving force to the pull-down power line SB in response to the first pull-down driving signal SAN0 activated faster by a predetermined time than the first pull-up driving signal SAP0.

As described above, the semiconductor memory apparatus according to this embodiment supplies the pull-up driving voltage and the pull-down driving voltage to the bit line sense amplifier unit 40 so that the bit line sense amplifier unit 40 can perform an amplification operation through three step amplification periods.

First the driving voltage supply unit 60B supplies a pull-down/pull-up driving voltage having a relatively small first pull-down/first pull-up driving force during a first amplification period t1. In this case, the pull-down driving voltage is supplied faster by the predetermined time than the pull-up driving voltage.

Subsequently, the driving voltage supply unit 60B supplies a pull-down/pull-up driving voltage having a second pull-down/second pull-up driving force greater than the first pull-down/first pull-up driving force during a second amplification period t2 after the first amplification period t1. In this case, the second amplification period t2 is divided into two periods. That is, the driving voltage supply unit 60B supplies a pull-up driving voltage having a first voltage level VDDA during a first period t2_1 of the second amplification period t2, and supplies a pull-up driving voltage having a second voltage level VCORE lower than the first voltage level VDDA during a second period t2_2 after the first period t2_1 of the second amplification period t2. Here, the pull-up driving voltage having the first voltage level VDDA is a voltage for over driving operation, and therefore, the bit line sense amplifier unit 40 performs an amplification operation using an over driving voltage VDDA during the first period t2_1 of the second amplification period t2.

When the pull-up/pull-down driving voltage having a relatively small driving force is first supplied during the first amplification period t1 before the over driving operation is performed, the voltage of the pull-up/pull-down power line RTO/SB is gently increased/decreased. In this case, the occurrence of power noise is more reduced by supplying the pull-down driving voltage and then supplying the pull-up driving voltage.

Although the pull-up driving voltage having the over driving voltage level VDDA is supplied at the time when the over driving voltage is supplied, i.e., at the time of the first period t2_1 of the second amplification period t2, the voltage of the pull-up power line RTO is gently increased. Thus, power noise is reduced, and accordingly, the offset voltage of the bit line sense amplifier unit 40 is decreased.

As the voltages of the pull-up power line RTO and the pull-down power line SB rapidly fluctuate, the power noise supplied to the bit line sense amplifier unit 40 is increased, and therefore, the offset voltage of the bit line sense amplifier unit 40 is increased. Thus, in this embodiment, the offset voltage of the bit line sense amplifier unit 40, caused by the power noise, is decreased by driving the pull-up/pull-down driving voltage having a relatively small driving force to the pull-up/pull-down power line RTO/SB before the over driving operation is performed. Accordingly, the bit line sense amplifier unit 40 can more stably amplifies data, and the reliability of data amplification can be improved.

As described above, detailed descriptions have been made according to embodiments of the present invention. For reference, although not directly related to the technical spirit of the present invention, embodiments including additional configurations can be illustrated for the purpose of more specific descriptions of the present invention. The configuration of an active high or active low for representing the activation state of signals and circuits may be changed depending on the embodiment. As occasion demands, the configuration of a transistor may be modified so as to implement the same function. That is, the configurations of PMOS and NMOS transistors may be replaced with each other, and the same function may be implemented using various types of transistors as occasion demands. Detailed descriptions according to modifications of the embodiments are very diverse, and can be readily construed by those skilled in the art. Therefore, the detailed descriptions will be omitted.

While certain embodiments have been described above, it will be understood to those skilled in the art that the embodiments described are by way of example only. Accordingly, the apparatus described herein should not be limited based on the described embodiments. Rather, the apparatus described herein should only be limited in light of the claims that follow when taken in conjunction with the above description and accompanying drawings.

What is claimed is:

1. A semiconductor memory apparatus, comprising:
a bit line sense amplifier unit configured to sense and amplify a signal provided from a memory cell using a pull-up driving voltage provided through a pull-up power line and a pull-down driving voltage provided through a pull-down power line; and
a driving voltage supply unit configured to supply the pull-down driving voltage having a first pull-down driving force during a first amplification period, and supply the pull-down driving voltage having a second pull-down driving force greater than the first pull-down driving force during a second amplification period after the first amplification period,
wherein the driving voltage supply unit supplies the pull-up driving voltage having a first voltage level during a first period of the second amplification period, and supplies the pull-up driving voltage having a second voltage level lower than the first voltage level during a second period after the first period.

2. The semiconductor memory apparatus according to claim 1, further comprising a power driving signal generation unit configured to generate first and second pull-down driving signals and first and second pull-up driving signals for control the driving voltage supply unit.

3. The semiconductor memory apparatus according to claim 2, wherein the driving voltage supply unit comprises:
a first pull-down driving unit configured to drive the pull-down driving voltage having the first pull-down driving force to the pull-down power line in response to the first pull-down driving signal;
a second pull-down driving unit configured to drive the pull-down driving voltage having the second pull-down driving force to the pull-down power line in response to the second pull-down driving signal activated after the first pull-down driving signal is activated;
a first pull-up driving unit configured to drive the pull-up driving voltage having the first voltage level to the pull-up power line in response to the first pull-up driving signal; and
a second pull-up driving unit configured to drive the pull-up driving voltage having the second voltage level to the pull-up power line in response to the second pull-up driving signal activated after the first pull-up driving signal is activated.

4. The semiconductor memory apparatus according to claim 3, wherein the driving voltage supply unit further comprises a precharge unit configured to precharge the pull-up power line and the pull-down power line to a precharge voltage in response to a precharge signal.

5. The semiconductor memory apparatus according to claim 3, wherein the power driving signal generation unit generates the first pull-down driving signal activated at a time of the first amplification period, a second pull-down driving signal activated at a time of the second amplification period, the first pull-up driving signal activated during the first period of the second amplification period, and the second pull-up driving signal activated during the second period of the second amplification period.

6. The semiconductor memory apparatus according to claim 1, wherein the bit line sense amplifier unit is configured as a differential amplifier circuit for sensing a difference in voltage between a main bit line and a sub bit line and amplifying the difference in voltage.

7. The semiconductor memory apparatus according to claim 1, wherein the memory cell provides a stored signal to the main bit line through a charge share operation with the main bit line.

8. The semiconductor memory apparatus according to claim 1, wherein, before the memory cell performs the charge share operation with the main bit line, the main bit line and the sub bit line are precharged to the precharge voltage.

9. A semiconductor memory apparatus, comprising:
a bit line sense amplifier unit configured to sense and amplify a signal provided from a memory cell using a pull-up driving voltage provided through a pull-up power line and a pull-down driving voltage provided through a pull-down power line; and
a driving voltage supply unit configured to supply the pull-up driving voltage having a first pull-up driving force during a first amplification period, and supply the pull-up driving voltage having a second pull-up driving force greater than the first pull-up driving force during a second amplification period after the first amplification period,
wherein the driving voltage supply unit supplies the pull-up driving voltage having a first voltage level during a first period of the second amplification period, and supplies the pull-up driving voltage having a second voltage level lower than the first voltage level during a second period after the first period.

10. The semiconductor memory apparatus according to claim 9, further comprising a power driving signal generation unit configured to generate a pull-down driving signal and first to third pull-up driving signals for control the driving voltage supply unit.

11. The semiconductor memory apparatus according to claim 10, wherein the driving voltage supply unit comprises:
a first pull-up driving unit configured to drive the pull-up driving voltage having the first pull-up driving force to the pull-up power line in response to the first pull-up driving signal;
a second pull-up driving unit configured to drive the pull-up driving voltage having the first voltage level to the pull-up power line in response to the second pull-up driving signal activated after the first pull-up driving signal is activated;
a third pull-up driving unit configured to drive the pull-up driving voltage having the second level to the pull-up power line in response to the third pull-up driving signal activated after the second pull-up driving signal is activated; and
a pull-down driving unit configured to drive the pull-down driving voltage to the pull-down power line in response to the pull-down driving signal.

12. The semiconductor memory apparatus according to claim 11, wherein the driving voltage supply unit further comprises a precharge unit configured to precharge the pull-up power line and the pull-down power line to a precharge voltage in response to a precharge signal.

13. The semiconductor memory apparatus according to claim 11, wherein the power driving signal generation unit generates the first pull-up driving signal activated at a time of the first amplification period, the second pull-up driving signal activated during the first period of second amplification period, the third pull-up driving signal activated during the second period of the second amplification period, and the pull-down driving signal activated at a time of the second amplification period.

14. The semiconductor memory apparatus according to claim 9, wherein the bit line sense amplifier unit is configured as a differential amplifier circuit for sensing a difference in voltage between a main bit line and a sub bit line and amplifying the difference in voltage.

15. The semiconductor memory apparatus according to claim 9, wherein the memory cell provides a stored signal to the main bit line through a charge share operation with the main bit line.

16. The semiconductor memory apparatus according to claim 9, wherein, before the memory cell performs the charge share operation with the main bit line, the main bit line and the sub bit line are precharged to the precharge voltage.

17. A semiconductor memory apparatus, comprising:
a bit line sense amplifier unit configured to sense and amplify a signal provided from a memory cell using a pull-up driving voltage provided through a pull-up power line and a pull-down driving voltage provided through a pull-down power line; and
a driving voltage supply unit configured to supply the pull-down/pull-up driving voltage having a first pull-down/first pull-up driving force during a first amplification period, and supply the pull-down/pull-up driving voltage having a second pull-down/pull-up driving force greater than the first pull-down/first pull-up driving force during a second amplification period after the first amplification period,
wherein the driving voltage supply unit supplies the pull-up driving voltage having a first voltage level during a first period of the second amplification period, and supplies the pull-up driving voltage having a second voltage level lower than the first voltage level during a second period after the first period.

18. The semiconductor memory apparatus according to claim 17, further comprising a power driving signal generation unit configured to generate first and second pull-down signals and first to third pull-up driving signals for control the driving voltage supply unit.

19. The semiconductor memory apparatus according to claim 18, wherein the driving voltage supply unit comprises:
a first pull-up driving unit configured to drive the pull-up driving voltage having the first pull-up driving force to the pull-up power line in response to the first pull-up driving signal;
a second pull-up driving unit configured to drive the pull-up driving voltage having the first voltage level to the pull-up power line in response to the second pull-up driving signal activated after the first pull-up driving signal is activated;
a third pull-up driving unit configured to drive the pull-up driving voltage having the second level to the pull-up power line in response to the third pull-up driving signal activated after the second pull-up driving signal is activated;
a first pull-down driving unit configured to drive the pull-down driving voltage having the first pull-down driving force to the pull-down power line in response to the first pull-down driving signal; and
a second pull-down driving unit configured to drive the pull-down driving voltage having the second pull-down driving force to the pull-down power line in response to the second pull-down driving signal activated after the first pull-down driving signal is activated.

20. The semiconductor memory apparatus according to claim 19, wherein the driving voltage supply unit further comprises a precharge unit configured to precharge the pull-up power line and the pull-down power line to a precharge voltage in response to a precharge signal.

21. The semiconductor memory apparatus according to claim 19, wherein the power driving signal generation unit generates the first pull-up driving signal activated at a time of the first amplification period, the second pull-up driving signal activated during the first period of second amplification period, the third pull-up driving signal activated during the second period of the second amplification period, the first pull-down driving signal activated at a time of the first amplification period, and the second pull-down driving signal activated at a time of the second amplification period.

22. The semiconductor memory apparatus according to claim 17, wherein the bit line sense amplifier unit is configured as a differential amplifier circuit for sensing a difference in voltage between a main bit line and a sub bit line and amplifying the difference in voltage.

23. The semiconductor memory apparatus according to claim 17, wherein the memory cell provides a stored signal to the main bit line through a charge share operation with the main bit line.

24. The semiconductor memory apparatus according to claim 17, wherein, before the memory cell performs the charge share operation with the main bit line, the main bit line and the sub bit line are precharged to the precharge voltage.

25. A semiconductor memory apparatus, comprising:
a bit line sense amplifier unit configured to sense and amplify a signal provided from a memory cell using a pull-up driving voltage provided through a pull-up power line and a pull-down driving voltage provided through a pull-down power line; and
a driving voltage supply unit configured to supply the pull-down/pull-up driving voltage having a first pull-down/first pull-up driving force during a first amplification period, in which the pull-down driving voltage is supplied faster by a predetermined time than the pull-up driving voltage, and supply the pull-down/pull-up driving voltage having a second pull-down/pull-up driving force greater than the first pull-down/first pull-up driving force during a second amplification period after the first amplification period,
wherein the driving voltage supply unit supplies the pull-up driving voltage having a first voltage level during a first period of the second amplification period, and supplies the pull-up driving voltage having a second voltage level lower than the first voltage level during a second period after the first period.

26. The semiconductor memory apparatus according to claim 25, further comprising a power driving signal generation unit configured to generate first and second pull-down driving signals and first to third pull-up driving signals for control the driving voltage supply unit.

27. The semiconductor memory apparatus according to claim 26, wherein the driving voltage supply unit comprises:
a first pull-up driving unit configured to drive the pull-up driving voltage having the first pull-up driving force to the pull-up power line in response to the first pull-up driving signal;
a second pull-up driving unit configured to drive the pull-up driving voltage having the first voltage level to the pull-up power line in response to the second pull-up driving signal activated after the first pull-up driving signal is activated;
a third pull-up driving unit configured to drive the pull-up driving voltage having the second level to the pull-up power line in response to the third pull-up driving signal activated after the second pull-up driving signal is activated;
a first pull-down driving unit configured to drive the pull-down driving voltage having the first pull-down driving force to the pull-down power line in response to the first pull-down driving signal activated faster by the predetermined time than the pull-up driving signal; and
a second pull-down driving unit configured to drive the pull-down driving voltage having the second pull-down driving force to the pull-down power line in response to the second pull-down driving signal activated after the first pull-down driving signal is activated.

28. The semiconductor memory apparatus according to claim 27, wherein the driving voltage supply unit further comprises a precharge unit configured to precharge the pull-up power line and the pull-down power line to a precharge voltage in response to a precharge signal.

29. The semiconductor memory apparatus according to claim 27, wherein the power driving signal generation unit generates the first pull-up driving signal activated after the first pull-down driving signal is activated during the first amplification period, the second pull-up driving signal activated during the first period of second amplification period, the third pull-up driving signal activated during the second period of the second amplification period, the first pull-down driving signal activated at a time of the first amplification period, and the second pull-down driving signal activated at a time of the second amplification period.

30. The semiconductor memory apparatus according to claim 25, wherein the bit line sense amplifier unit is configured as a differential amplifier circuit for sensing a difference in voltage between a main bit line and a sub bit line and amplifying the difference in voltage.

31. The semiconductor memory apparatus according to claim 25, wherein the memory cell provides a stored signal to the main bit line through a charge share operation with the main bit line.

32. The semiconductor memory apparatus according to claim 25, wherein, before the memory cell performs the charge share operation with the main bit line, the main bit line and the sub bit line are precharged to the precharge voltage.
